(19) United States
(12) Patent Application Publication
(10) Pub. No.: US 2011/0304245 A1
(43) Pub. Date: Dec. 15, 2011

(54) ELECTRONIC CONTROL UNIT

(75) Inventor: Mitsuaki KONDO, Inazawa-City (JP)

(73) Assignee: DENSO CORPORATION, Kariya-city (JP)

(21) Appl. No.: 13/156,640

(22) Filed: Jun. 9, 2011

(30) Foreign Application Priority Data
Jun. 15, 2010 (JP) 2010-136106

(51) Int. Cl. H05K 5/03; H05K 5/02

(52) U.S. Cl. 312/223.1

(57) ABSTRACT

An electronic control unit is adapted to be in contact with and attached on an attachment object surface of a vehicle having thermal conductivity. The unit includes a thermally-conductive outer casing and an attachment surface. The outer casing accommodates a heat-generating electronic component. The attachment surface has a convex shape and is in contact with the attachment object surface.

### CROSS REFERENCE TO RELATED APPLICATION

This application is based on and incorporates herein by reference Japanese Patent Application No. 2010-136106 filed on Jun. 15, 2010.

### BACKGROUND OF THE INVENTION

1. Field of the Invention

The present invention relates to an electronic control unit that includes a thermally conductive outer casing in which a heat-generating electronic component is accommodated, the unit being pressed and attached on an attachment object surface of a vehicle having thermal conductivity.

2. Description of Related Art

Conventionally, as this kind of electronic control unit, an electronic control unit (ECU) that controls an engine disposed in a vehicle is known.

As illustrated in FIG. 8, a conventional ECU 180 includes a circuit board 130 on which electronic components generating heat, such as a power transistor, are mounted; a case 120 that accommodates this circuit board 130; and a plate-like cover 190 that covers an opening 127 of this case 120. The case 120 and the cover 190 are formed from thermally conductive materials that consist primarily of iron, for example. A connector 133 for connection to various kinds of sensor, such as a crank angle sensor and a cam angle sensor, is provided on a surface 131 of the circuit board 130.

A heat release member 149 is provided on a surface 141 of the cover 190. The heat release member 149 is contact with the electronic components generating heat on the circuit board 130 to conduct the heat generated from the electronic components to the cover 190. Attachment pieces 147 are formed on both side surfaces 142, 143 of the cover 190, and a bolt insertion hole 148, through which a bolt 160 (FIGS. 9A to 9D) is inserted, is formed in each attachment piece 147. The ECU 180 configured as described above is fixed by fastening the bolt 160 inserted through each attachment piece 147 into a bolt hole formed on a side wall of an engine compartment. See, for example, JP-A-2007-201283 (paragraph 31 and FIG. 1).

It is often the case that an attachment surface of the side wall of the engine compartment, on which the ECU is attached, is not a complete flat surface. For example, a recess 151 may be formed as illustrated in FIG. 9A or the recess 151 and a projection 152 may be formed as illustrated in FIG. 9B, on an attachment object surface 156 of a side wall 150. The side wall 150 is formed from thermally conductive materials that consist primarily of iron, for example.

Accordingly, if the ECU 180 is attached on such an attachment object surface 156, as illustrated in FIGS. 9C and 9D, a clearance E is formed between the attachment surface 145 of the cover 190 of the ECU 180, and the side wall 150. As a result, thermal contact resistance between the attachment surface 145 of the cover 190 and the side wall 150 becomes great. Therefore, the heat generated from the heat-generating electronic components is not easily conducted to the side wall 150 through the cover 190 to cause low radiation efficiency.

### SUMMARY OF THE INVENTION

The present invention addresses at least one of the above disadvantages.

According to the present invention, there is provided an electronic control unit adapted to be in contact with and attached on an attachment object surface of a vehicle having thermal conductivity. The unit includes a thermally-conductive outer casing and an attachment surface. The outer casing accommodates a heat-generating electronic component. The attachment surface has a convex shape and is in contact with the attachment object surface.

### BRIEF DESCRIPTION OF THE DRAWINGS

The invention, together with additional objectives, features and advantages thereof, will be best understood from the following description, the appended claims and the accompanying drawings in which:

FIG. 1 is an exploded perspective view illustrating a configuration of an ECU in accordance with a first embodiment of the invention;

FIG. 2A is an end view illustrating the ECU in FIG. 1 after its assembly;

FIG. 2B is a longitudinal sectional view illustrating a side wall of an engine compartment in accordance with the first embodiment;

FIG. 2C is a longitudinal sectional view illustrating the side wall of the engine compartment in accordance with the first embodiment;

FIG. 2D is a longitudinal sectional view illustrating the ECU attached to the side wall in accordance with the first embodiment;

FIG. 3A is a longitudinal sectional view illustrating the ECU in FIG. 2A with the ECU attached to the side wall of the engine compartment in accordance with the first embodiment;

FIG. 3B is a diagram illustrating a point of application at the side wall at the time of attachment of the ECU in accordance with the first embodiment;

FIG. 4A is a plan view illustrating an ECU in accordance with a second embodiment of the invention;

FIG. 4B is a front view illustrating the ECU in accordance with the second embodiment;

FIG. 4C is a front view illustrating the ECU in accordance with the second embodiment;

FIG. 4D is a right side view illustrating the ECU in accordance with the second embodiment;

FIG. 4E is a right side view illustrating the ECU in accordance with the second embodiment;

FIG. 5A is a longitudinal sectional view illustrating an ECU in accordance with a third embodiment of the invention;

FIG. 5B is a longitudinal sectional view illustrating the ECU in FIG. 5A with the ECU attached to a side wall of an engine compartment in accordance with the third embodiment;

FIG. 6 is an exploded perspective view illustrating a configuration of an ECU in accordance with a fourth embodiment of the invention;

FIG. 7A is a longitudinal sectional view illustrating the ECU in FIG. 6 with the ECU attached to a side wall of an engine compartment;

FIG. 7B is a longitudinal sectional view illustrating the side wall in accordance with the fourth embodiment;

FIG. 7C is a longitudinal sectional view illustrating the ECU in FIG. 6 with the ECU attached to the side wall in FIG. 7B;

FIG. 8 is an exploded perspective view illustrating a configuration of a previously proposed ECU;

FIG. 9A is a longitudinal sectional view illustrating a side wall of a previously proposed engine compartment;

FIG. 9B is a longitudinal sectional view illustrating the side wall of the previously proposed engine compartment;

FIG. 9C is a longitudinal sectional view illustrating the previously proposed ECU with this ECU attached to the side wall; and

FIG. 9D is a longitudinal sectional view illustrating the previously proposed ECU with this ECU attached to the side wall.

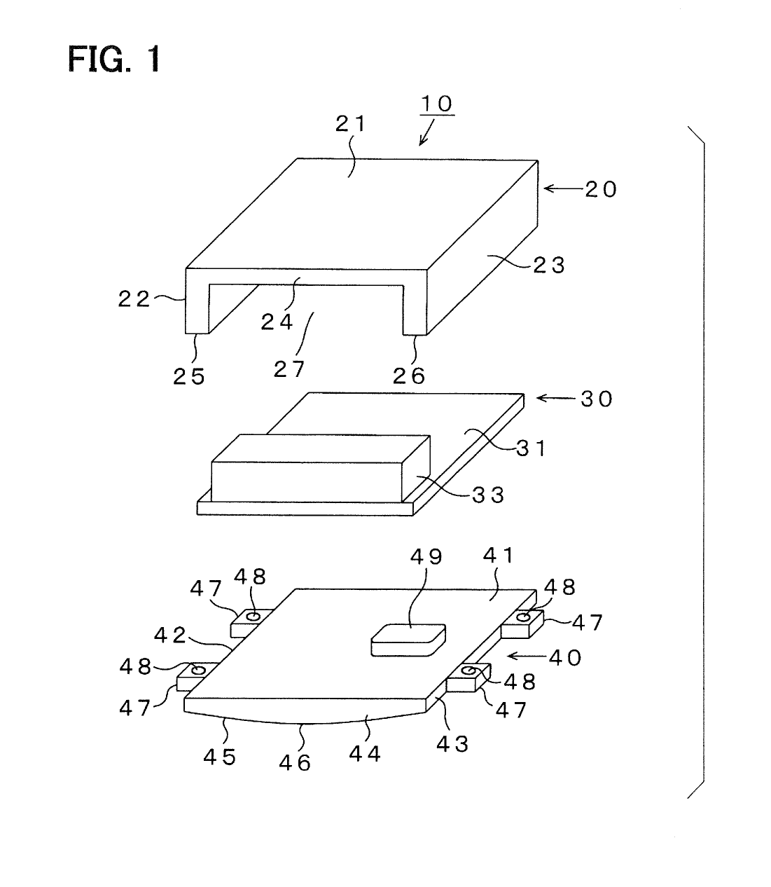

### DETAILED DESCRIPTION OF THE INVENTION

### First Embodiment

An electronic control unit in accordance with a first embodiment of the invention will be described in reference to the accompanying drawings. In the following embodiments, the description will be given by taking an ECU for example as the electronic control unit.

An ECU 10 of the present embodiment includes a case 20, a circuit board 30, and a cover 40. The cover 40 is attached to the case 20 by an attachment member (not shown) such that its surface 41 is in contact with respective lower ends 25, 26 of side walls 22, 23 of the case 20, which are opposed to each other. At the time of this attachment of the cover 40 to the case 20, a connector 33 on the circuit board 30 is accommodated in an opening 27 formed at an end face 24 of the case 20.

An attachment surface 45, which is formed on a surface of the cover 40, is formed entirety in a convex shape that is swollen like a circular arc. In other words, the attachment surface 45 is formed into an outer periphery shape of a part of a cylinder, which is on the opposite side from a cut surface that is made when this part of the cylinder is cut along a line parallel to its central axis. A sectional shape obtained when the cover 40 is cut parallel to its end face 44 is the same convex shape as the end face 44.

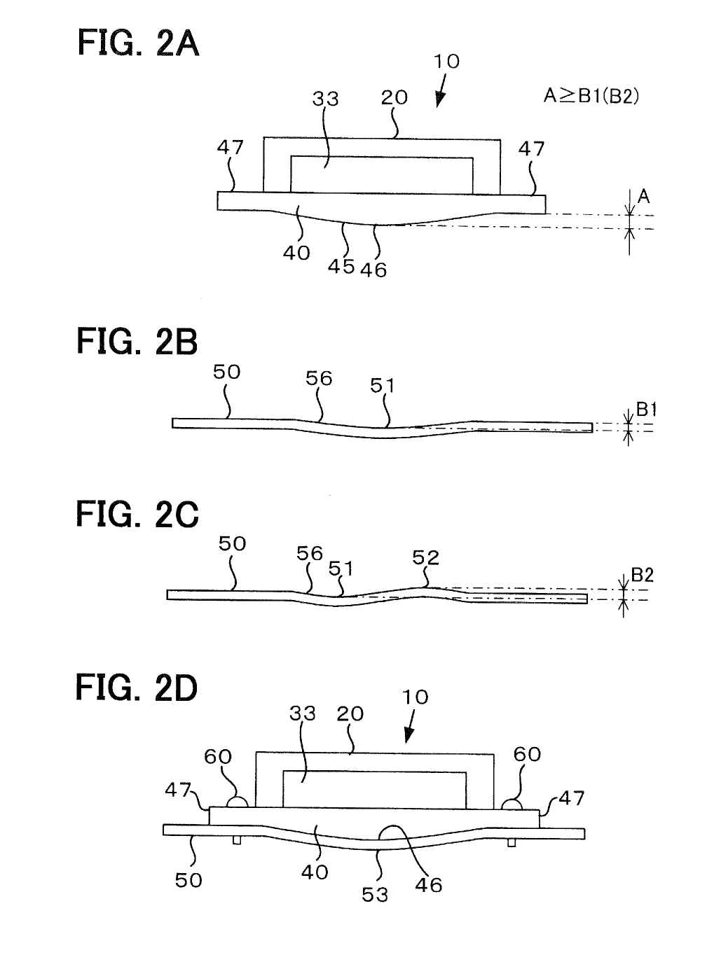

Height A of a convex shape of the attachment surface 45 of the ECU 10 illustrated in FIG. 2A is determined based on depth of a recess formed on the attachment object surface 56 that is a surface of the side wall 50 of the engine compartment on which the ECU 10 is attached; and height of a projecting shape formed on the surface 56.

More specifically, if a recess 51 having a depth B1 is formed on the attachment object surface 56 provided for the side wall 50 of the engine compartment as illustrated in FIG. 2B, the attachment surface 45 is formed such that a height A of the attachment surface 45 is equal to or larger than the depth B1 of the recess 51 (A≧B1). Moreover, if a projection 52 having a height B2 is formed on the attachment object surface 56 as illustrated in FIG. 2C, the attachment surface 45 is formed such that the height A of the attachment surface 45 is equal to or larger than the height B2 of the projection 52 (A≧B2).

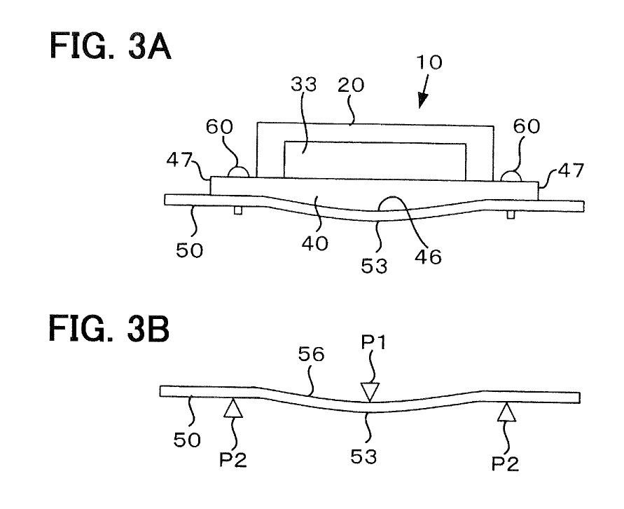

P1 indicated in FIG. 3B is a point of application of force by a vertex 46 of the attachment surface 45 at the time of the attachment of the ECU 10 on the side wall 50; and P2 is a point of application of force by the bolt 60 at the time of fastening of the bolt 60, which is inserted through the attachment piece 47 of the cover 40, in the side wall 50.

The ECU 10 is brought into contact with the attachment object surface 56 of the side wall 50 of the engine compartment, and the bolt insertion hole 48 of the attachment piece 47, and a bolt hole (female screw hole) formed on the attachment object surface 56 are made to coincide with each other. Then, the bolt 60 is inserted into the bolt insertion hole 48 to be screwed in the bolt hole. Accordingly, the vertex 46 of the attachment surface 45 of the ECU 10 serves as the point of application P1 in the direction of the side wall, and the bolt 60 screwed in serves as the point of application P2 in the direction of the ECU.

After that, when the bolt 60 continues being screwed in, the side wall 50, which defines the attachment object surface 56, yields in a concave shape so as to conform to the attachment surface 45. Even in a case where there are recessed and projecting portions on the attachment object surface 56, these recessed and projecting portions are forcibly adjusted by pressing force of the attachment surface 45, and the side wall 50 changes into a shape 53 corresponding to the attachment surface 45. When the bolt 60 further continues being screwed in, the attachment surface 45 and the attachment object surface 56 are closely-attached to each other to reduce a non-contact part between the surfaces 45 and 56. Accordingly, their contact area increases, so that thermal contact resistance becomes small.

As described above, in the ECU 10 of the first embodiment, because the attachment surface 45 is formed in a convex shape, the attachment object surface 56 can be bent by this convex shape at the time of the attachment of the ECU 10 with the ECU 10 pressed on the attachment object surface 56 of the engine compartment. Accordingly, their contact area can be increased as a result of the reduction of the non-contact part of the attachment surface 45 and the attachment object surface 56. Thus, the thermal contact resistance between the surfaces 45 and 56 can be made small so as to enhance radiation efficiency.

In addition, even if the recessed and projecting portions are formed on the attachment object surface 56 as illustrated in FIG. 2C, the attachment object surface 56 can be sagged by forming the attachment surface 45 of the ECU 10 into a convex shape having the height A, which is equal to or greater than the heights B1, B2 of the recessed and projecting portions of the attachment object surface 56. As a result of the decrease of the non-contact part between the attachment surface 45 and the attachment object surface 56, their contact area is increased to improve the radiation efficiency.

### Second Embodiment

A second embodiment of the invention will be described with reference to the accompanying drawings.

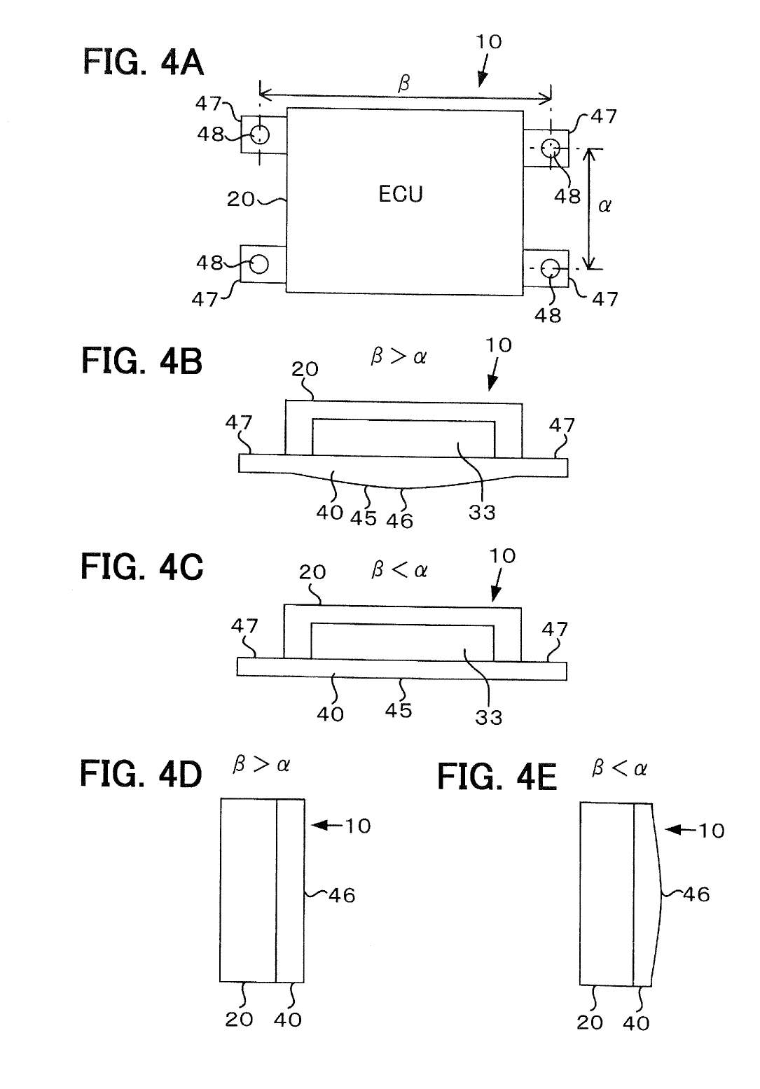

As illustrated in FIG. 4A, a distance between bolt insertion holes 48 formed through a pair of attachment pieces 47 projecting from the same side surface of a cover 40 is α; and a distance between the bolt insertion holes 48 formed through the pair of attachment pieces 47 projecting from both side surfaces of the cover 40 is β. A ratio between these α and β corresponds to a ratio (aspect ratio) between length and width of an attachment surface 45. In the case of β>α, i.e., in the case of α being in a lateral (shorter) direction and β being in a longitudinal direction, the cover 40 is formed such that only a longitudinal section obtained when the cover 40 is cut along the longitudinal direction has a convex shape, i.e., such that the attachment surface 45 has a convex shape when viewed from its front side, as illustrated in FIGS. 4B and 4D.

In the case of β<α, i.e., in the case of α being in the longitudinal direction and β being in the shorter direction, the cover 40 is formed such that only a longitudinal section obtained when the cover 40 is cut along the longitudinal direction has a convex shape, i.e., such that the attachment surface 45 has a convex shape when viewed from its side surface as illustrated in FIGS. 4C and 4E. As above, by forming the cover 40 such that the attachment surface 45 has a convex shape when the cover 40 is cut along the longitudinal direction, a distance between the vertex and the bottom portion of the convex shape can be made large. Accordingly, when the attachment object surface 56 is warped by the convex shape of the attachment surface 45, a bending load applied to an attachment object surface 56 can be made small. Therefore, force required for the attachment of the ECU 10 can be made small.

In addition, the cover 40 may also be formed such that each cross section of the attachment surface 45 along the longitudinal direction and shorter direction has a convex shape. By use of this attachment surface 45, the attachment object surface 56 can be bent in multiple directions. As a result, the contact area between the attachment surface 45 and the attachment object surface 56 is not easily influenced by a sectional shape of the surface 56.

### Third Embodiment

A third embodiment of the invention will be described with reference to the accompanying drawings.

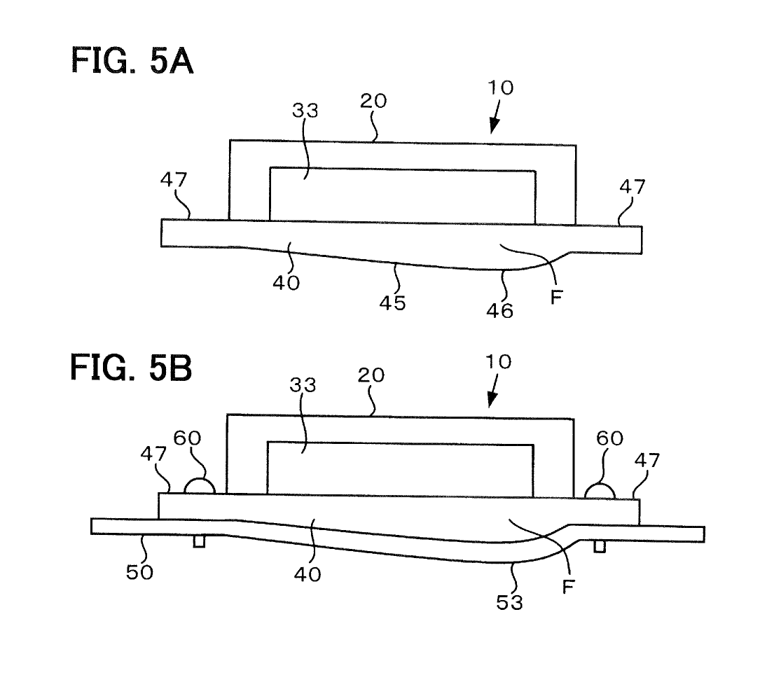

A heat-generating electronic component such as a power transistor is not necessarily disposed at the center of a circuit board 30. In such a case, a high temperature portion, i.e., a region (hereinafter referred to as a heat generation concentration region) at which heat generation concentrates, exists at a place that is deviated away from the center of a cover 40 as indicated by a numeral F in FIGS. 5A and 5B. Accordingly, the cover 40 is formed such that an attachment surface 45 has a convex shape having a vertex 46 near the heat generation concentration region F.

By forming the attachment surface 45 in this manner, thermal contact resistance of the heat generation concentration region F with the attachment object surface 56 can be minimized. Thus, the radiation efficiency can be further improved.

### Fourth Embodiment

A fourth embodiment of the invention will be described with reference to the accompanying drawings.

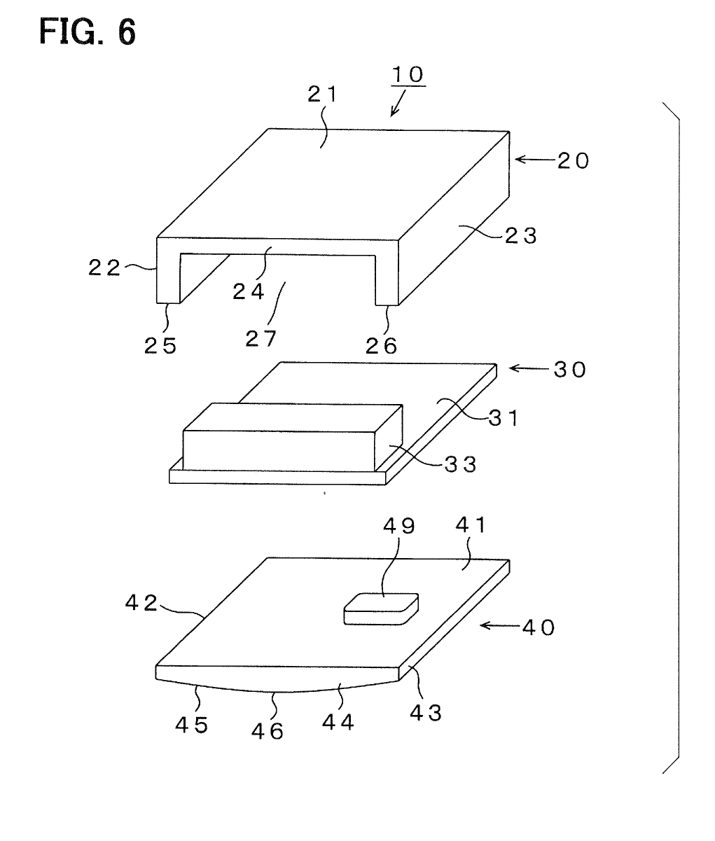

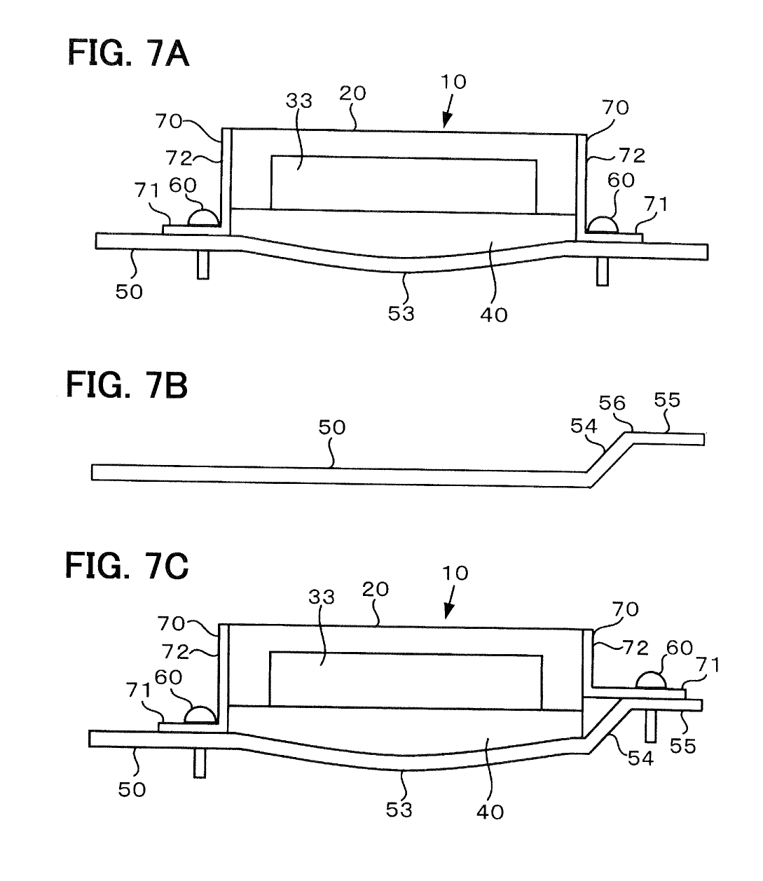

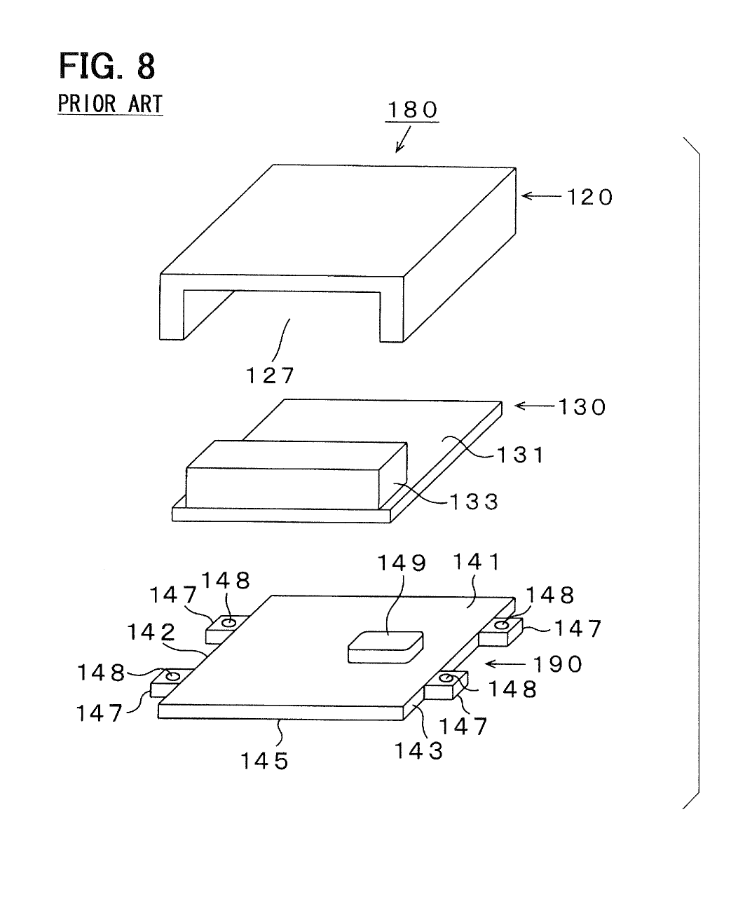

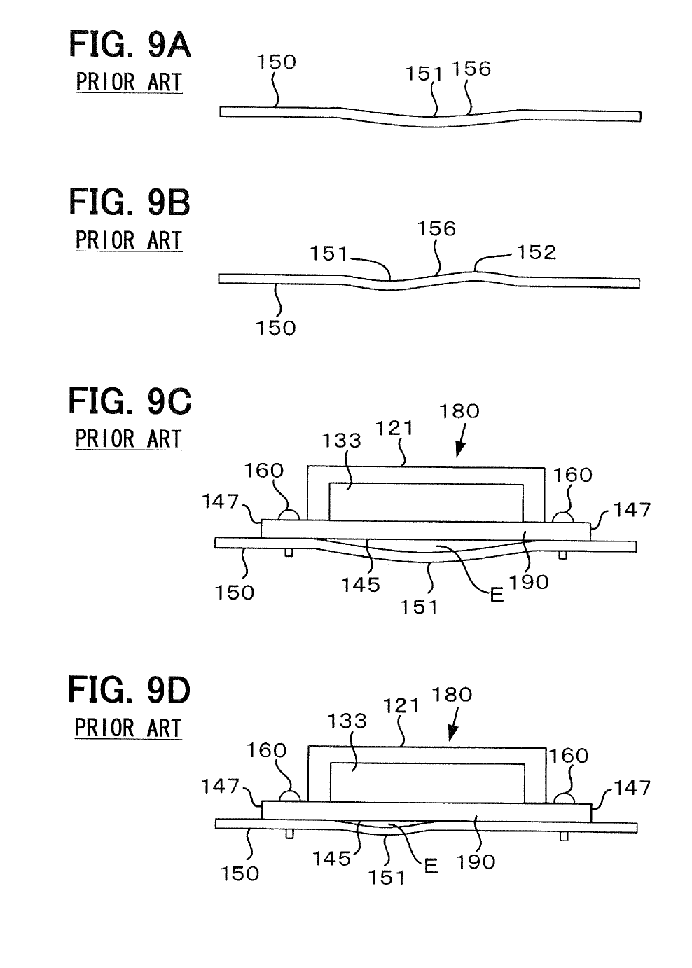

As illustrated in FIG. 6, an attachment piece 47 is not provided for a cover 40 that constitutes an ECU 10 of the present embodiment. Alternatively, as shown in FIG. 7A, the ECU 10 includes a set of brackets 70 which are indirect members. A longitudinal section of each bracket 70 is formed into an L-shape, and a bolt insertion hole is formed through each horizontal part 71 of the bracket 70. Moreover, a reverse face of a vertical part 72 of each bracket 70 is firmly fixed on side surfaces of a case 20 and the cover 40.

As described above, the ECU 10 of the present embodiment is attached on a side wall 50 using the bracket 70, which is an indirect member. Accordingly, a special cover 40 having the attachment piece 47 does not need to be produced respectively for different sizes of the ECU 10. Thus, a production cost for the cover 40 can be reduced.

In an example in FIG. 7B, one end of an attachment object surface 56 of the side wall 50 is crooked. The crooked part of the side wall 50 is constituted of an inclined part 54 and a horizontal part 55, and a bolt hole, in which a bolt 60 is fastened, is formed on the horizontal part 55. Accordingly, the heights, at which the bolts 60 are fastened, are different at both ends of the ECU 10. For that reason, as illustrated in FIG. 7C, one of the brackets 70 is formed such that its vertical part 72 is shorter and its horizontal part 71 is longer, and the bolt 60 can thereby be fastened in the bolt hole of the horizontal part 55.

As above, if the attachment object surface 56 of the side wall 50 is not flat but crooked, the ECU 10 can be attached to the attachment object surface 56 by producing the bracket 70 in accordance with the crooked shape of the side wall 50. Therefore, even in the case in which there are more than one kind of attachment object surface 56, the ECU 10 can be attached on the attachment object surface 56 without having to change the shape of the cover 40 by use of the brackets 70 corresponding to the attachment object surfaces 56.

Modifications of the above embodiments will be described. If the heat-generating electronic component is mounted on a surface 31 of the circuit board 30, a heat release member 49 may be provided on a reverse face of the case 20 to be in contact with this heat-generating electronic component; a surface 21 of the case 20 may be formed into a convex shape; the attachment pieces 47 may be formed from both side walls 22, 23 of the case 20; and the surface 21 of the case 20 may be pressed and attached on the attachment object surface 56.

In the above-described embodiments, the case of the entire attachment surface 45 having a convex shape that is swollen in a circular arc shape, is explained. Alternatively, the surface 45 may also be formed into a convex shape such that a part of the attachment surface 45 is swollen in a circular arc shape corresponding to the shape of the attachment object surface 56. In the above-described embodiments, the ECU attached to the side wall of the engine compartment is explained. Nevertheless, the invention may be applicable also to an ECU that is attached on a wall of those other than the engine compartment.

The ECU 10 in accordance with the above embodiments of the invention can be summarized as follows.

The ECU 10 is adapted to be in contact with and attached on an attachment object surface 56 of a vehicle having thermal conductivity. The ECU 10 includes a thermally-conductive outer casing 20 or 40 and an attachment surface 45. The outer casing 20 or 40 accommodates a heat-generating electronic component. The attachment surface 45 has a convex shape and is in contact with the attachment object surface 56.

Accordingly, since the attachment surface 45 of the ECU 10 is formed in a convex shape, at the time of the attachment of the ECU 10 on the attachment object surface 56 with the ECU 10 in contact with the surface 56 of a vehicle, the attachment object surface 56 can be bent into a shape that conforms to the convex shape of the attachment surface 45 by the convex shape. As a result, a noncontact part between the attachment surface 45 and the attachment object surface 56 is reduced, so that their contact area can be increased. Therefore, thermal contact resistance between the surfaces 45 and 56 can be made small, and radiation efficiency can thereby be improved.

The attachment surface 45 is formed in the convex shape, which may have a height A that is equal to or greater than heights B1 and B2 of recessed and projecting portions on the attachment object surface 56.

Particularly, even in the case of an irregular shape being formed on the attachment object surface 56 of the vehicle, by forming the attachment surface 45 of the ECU 10 into the convex shape having the height A, which is equal to or greater than the heights B1, B2 of recessed and projecting portions on the attachment object surface 56, the attachment object surface 56 can be bent into a shape corresponding to the convex shape of the attachment surface 45. Accordingly, as a result of the reduction of a noncontact part between the surfaces 45 and 56, their contact area is increased and the radiation efficiency can be improved.

A sectional surface of the attachment surface 45 along a longer direction thereof may have a convex shape.

Since the cross section of the attachment surface 45 along its longitudinal direction has a projecting shape, an interval between the vertex 46 and the bottom portion of the convex shape of the attachment surface 45 can be made larger. Accordingly, when the attachment object surface 56 is curved by the convex shape of the attachment surface 45, a bending load applied to the attachment object surface 56 can be made small. Thus, the force required for the attachment of the ECU 10 can be made small.

Each of sectional surfaces of the attachment surface 45 along a longer direction and a shorter direction thereof may have a convex shape.

Because cross sections of the attachment surface 45 along its longitudinal and shorter directions have convex shapes, respectively, the attachment object surface 56 can be sagged in multiple directions. Accordingly, a contact area between the surfaces 45 and 56 is not easily influenced by a sectional shape of the attachment object surface 56.

The attachment surface 45 is formed in the convex shape, which may have a vertex 46 close to a high-temperature portion F of the outer casing 40. Because the attachment surface 45 is formed in a convex shape having its vertex 46 near a high temperature portion within the attachment surface 45, thermal contact resistance of the high temperature portion with the attachment object surface 56 can be minimized. Accordingly, the radiation efficiency can be further improved.

The ECU 10 may further include a heat release member 49 between a reverse surface 41 of the attachment surface 45 and the electronic component.

The heat release member 49 is disposed between the reverse face 41 of the attachment surface 45 and the electronic component. Accordingly, the heat generated from the electronic component can be conducted from the heat release member 49 to the attachment object surface 56 through the attachment surface 45.

The outer casing 40 may include an attachment piece 47 through which a bolt insertion hole 48 is formed. The ECU 10 may further include a bolt 60, which is inserted in the bolt insertion hole 48 and fastened to the attachment object surface 56 so that the ECU 10 is pressed and attached on the attachment object surface 56.

Through the operation of fastening the bolt 60, which is inserted in the bolt insertion hole 48 of the attachment piece 47 for the outer casing 20 or 40, the attachment object surface 56 is bent by the convex shape of the attachment surface 45. As a result of the reduction of the non-contact part of the attachment surface 45 and the attachment object surface 56, their contact area can be increased.

The ECU 10 may further include: an indirect member 70 which is attached to the outer casing 20 or 40 and through which a bolt insertion hole is formed; and a bolt 60 which is inserted in the bolt insertion hole and fastened to the attachment object surface 56, so that the ECU 10 is pressed and attached on the attachment object surface 56.

Through the operation of fastening the bolt 60, which is inserted through the bolt insertion hole of the indirect member 70 that is attached to the outer casing 20 or 40, the attachment object surface 56 is bent by the convex shape of the attachment surface 45, and the contact area between the surfaces 45 and 56 can thereby be increased. Even in the case in which two or more kinds of the attachment object surfaces 56 exist, the ECU 10 can be attached to the attachment object surface 56 without changing a shape of the outer casing 20 or 40 by means of the indirect member 70 that is in accordance with the attachment object surface 56.

The outer casing 20 or 40 may include: a case 20 that accommodates the electronic component; and a cover 40 that covers an opening 27 of the case 20. The attachment surface may be a surface 21 of the case 20.

As a result of the attachment of a surface side of the case 20, which constitutes the outer casings 20 and 40, to the attachment object surface 56, the radiation efficiency can be improved.

The outer casing 20 or 40 may include: a case 20 that accommodates the electronic component; and a cover 40 that covers an opening 27 of the case 20. The attachment surface 45 may be a surface of the cover 40.

As a result of the attachment of a surface side of the cover 40, which constitutes the outer casings 20 and 40, on the attachment object surface 56, the radiation efficiency can be improved.

Additional advantages and modifications will readily occur to those skilled in the art. The invention in its broader terms is therefore not limited to the specific details, representative apparatus, and illustrative examples shown and described.

What is claimed is:

1. An electronic control unit adapted to be in contact with and attached on an attachment object surface of a vehicle having thermal conductivity, the unit comprising:
a thermally-conductive outer casing that accommodates a heat-generating electronic component; and
an attachment surface that has a convex shape and is in contact with the attachment object surface.

2. The electronic control unit according to claim 1, wherein the attachment surface is formed in the convex shape, which has a height that is equal to or greater than heights of recessed and projecting portions on the attachment object surface.

3. The electronic control unit according to claim 1, wherein a sectional surface of the attachment surface along a longer direction thereof has a convex shape.

4. The electronic control unit according to claim 1, wherein each of sectional surfaces of the attachment surface along a longer direction and a shorter direction thereof has a convex shape.

5. The electronic control unit according to claim 1, wherein the attachment surface is formed in the convex shape, which has a vertex close to a high-temperature portion of the outer casing.

6. The electronic control unit according to claim 1, further comprising a heat release member between a reverse surface of the attachment surface and the electronic component.

7. The electronic control unit according to claim 1, wherein the outer casing includes an attachment piece through which a bolt insertion hole is formed, the unit further comprising a bolt, which is inserted in the bolt insertion hole and fastened to the attachment object surface so that the electronic control unit is pressed and attached on the attachment object surface.

8. The electronic control unit according to claim 1, further comprising:
an indirect member which is attached to the outer casing and through which a bolt insertion hole is formed; and
a bolt which is inserted in the bolt insertion hole and fastened to the attachment object surface, so that the electronic control unit is pressed and attached on the attachment object surface.

9. The electronic control unit according to claim 1, wherein:
the outer casing includes:
a case that accommodates the electronic component; and
a cover that covers an opening of the case; and
the attachment surface is a surface of the case.

10. The electronic control unit according to claim 1, wherein:
the outer casing includes:
a case that accommodates the electronic component; and
a cover that covers an opening of the case; and
the attachment surface is a surface of the cover.
